(19) United States
(12) Patent Application Publication
(10) Pub. No.: US 2008/0067440 A1
(43) Pub. Date: Mar. 20, 2008

(54) MACHINING OF MICROSTRUCTURES

(76) Inventor: David COX, Surrey (GB)

Correspondence Address: Intellectual Property Dept.;Dewitt Ross & Stevens SC, 2 East Mifflin Street, Suite 600, Madison, WI, 53703-2865, US

(21) Appl. No.: 11/748,609

(22) Filed: May 15, 2007

(30) Foreign Application Priority Data
May 16, 2006 (GB) GB0609718.2

(51) Int. Cl. H01J 37/08

(52) U.S. Cl. 250/492.21

(57) ABSTRACT

There are disclosed methods for machining components, such as thermocouples 280 or SQUIDs 330, using ion beam milling. Ion beam milling is performed on a material 200 to expose a sliver 240. A sharp probe 161 is then attached to the sliver 240, for example by deposition of a tungsten weld 250. Further ion beam milling 261, 262, 263 is then performed to separate the sliver 240 from the material 200. The sliver 240 is then ion beam milled to produce the device 280, 330. In some embodiments, the thermocouple 280 is mounted to a substrate such as a silicon wafer having integrated signal conditioning circuitry. The invention allows small components (of the order of 1 μm) to be accurately manufactured without being constrained by typical lithographic constraints.

This invention is concerned with methods of micro-machining structures and is also concerned with the resultant structures.

According to the present invention, there are provided methods for machining slivers, components, or devices, such as thermocouples 280 or SQUIDs 330, using ion beam milling. In most embodiments, ion beam milling is performed on a material 200 to expose a sliver 240. A sharp probe 161 is then attached to the sliver 240, for example by deposition of a tungsten weld 250. Further ion beam milling 261, 262, 263 is then performed to separate the sliver 240 from the material 200. The sliver 240 is then ion beam milled to produce the device 280, 330. In some embodiments, the thermocouple 280 is mounted to a substrate such as a silicon wafer having integrated signal conditioning circuitry. The invention allows small components (of the order of 1 μm) to be accurately manufactured without being constrained by typical lithographic constraints.

An advantage of the present invention is that small structures may be accurately and repeatably manufactured. For example, a thermocouple fabricated using a method described below may have a length of 10 μm, a width of 5 μm, a thickness of 100 nm and a 50 nm radius at the junction end of the thermocouple (for an active volume of 100 nm³). Such a thermocouple has a low thermal heat capacity and thus has a rapid response time.

In some embodiments the structures may have dimensions of the order of a few micrometers (μm) but the structures may be smaller than this (e.g. of the order of a few 25 nm) or larger (of the order of a few mm).

The structures may have a single layer or may be multi-layered. For example, SQUIDs (superconducting quantum interference device) may have a single layer whereas thermocouples will generally have two layers (in order to produce an electrical junction between two dissimilar materials). In some embodiments, a sacrificial layer is provided to act as a protective layer (and/or to provide additional mechanical support) during processing of the microstructure.

Another advantage of the present invention is that devices (such as thermocouples or SQUIDs) may be made free standing with respect to a substrate. For example, three orthogonally arranged SQUIDs may be mounted on a substrate, such that one of the SQUIDs is fabricated in the plane of the substrate whereas the other two SQUIDs are perpendicular to each other and orientated normal to the substrate.

Conventional lithographic processing is largely confined to quasi two-dimensional structures and processes, where each layer in a device is deposited, and then masked or etched before the next layer is deposited. Conventional lithographic processes are not well suited to producing free standing multilayer structures, and are also often limited as the combination of materials that may be used. For example,

### DESCRIPTION OF FIGURES

Preferred embodiments of the present invention will now be described with reference to the following Figures in which:

FIG. 1 is a schematic diagram of a dual beam FIB (focussed ion beam) instrument. The dual beam FIB instrument has an electron beam and a FIB.

FIG. 2 shows a multilayer bulk material, a thermocouple formed from the multilayer bulk material and the intermediate stages in the forming of the thermocouple from the multilayer bulk material:

FIG. 2a shows a multilayer bulk material;

FIG. 2b shows the multilayer bulk material after material has been removed by FIB milling on either side of a sliver;

FIG. 2c shows a cross-section through the plane 2c-2c′ of FIG. 2b;

FIG. 2d shows the tip of a micro-positioner that has been attached to the sliver that is shown in FIGS. 2b and 2c;

FIG. 2e shows the sliver after it has been detached from the multilayer bulk substrate by FIB milling;

FIG. 2f shows a cross-section through the sliver, in the plane 2f-2f of FIG. 2e;

FIG. 2g shows the sliver of FIG. 2e in more detail, and also highlights material that is to be removed from the sliver; and

FIG. 2h shows the finished thermocouple, after the material highlighted in FIG. 2g has been removed.

FIG. 3 shows a sliver used to form a SQUID and also shows the finished SQUID:

FIG. 3a shows a sliver before unwanted material is removed by FIB milling;

FIG. 3b shows the loop of the SQUID after unwanted material has been removed (the loop of the SQUID is still attached to a substrate).

### DESCRIPTION OF PREFERRED EMBODIMENTS

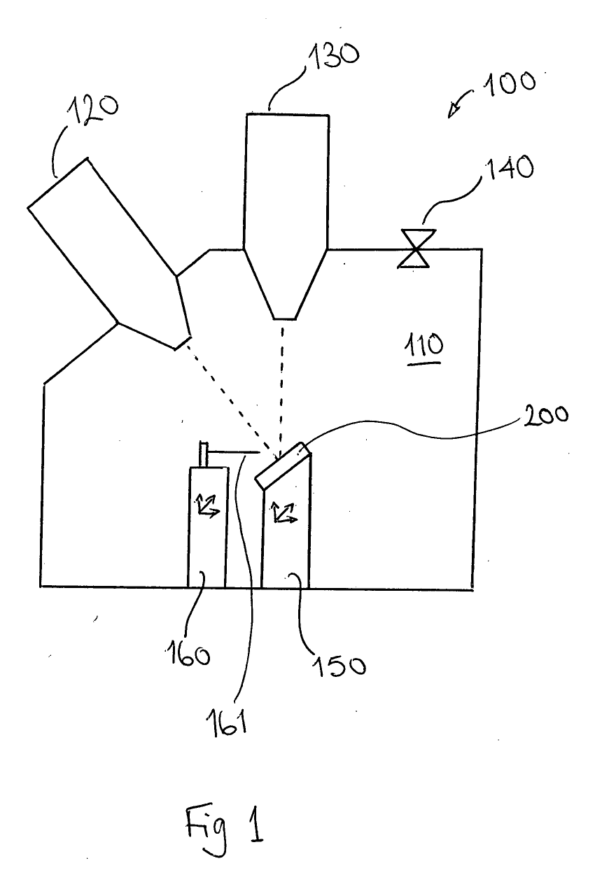

FIG. 1 shows a schematic diagram of a dual beam FIB (focussed ion beam) instrument 100. An example of such a dual beam FIB instrument is the Nova 600 NanoLab, manufactured by FEI Company, USA. The FIB instrument 100 comprises a vacuum chamber 110, an ion column 120, an electron column 130, a gas port 140, a sample manipulation stage 150 and a micro-manipulator 160.

The ion column 120 comprises a source (not shown) of ions, electrodes (not shown) for accelerating the ions though an electric field, and electromagnets (not show) for focussing the beam of ions. In this embodiment, the source supplies gallium ions for acceleration by an electric potential of up to 30 kV (kilovolts). The electromagnets focus the beam to a spot size of the order of 7 nm. The beam current is up to 20 nA (nanoamps). The momentum of the gallium ions is such that they can be used to “mill” away other atoms—the gallium ions knock other atoms with sufficient force to dislodge the atoms from their neighbouring atoms and thus remove the atoms from a surface.

The electron column 130 is similar to the ion column but accelerates electrons instead of gallium ions. In this embodiment, the electron column accelerates electrons by up to 30 kV, with a spot size of the order of 1 nm, and a beam current of up to 20 nA. The electron beam may be used as part of an electron microscope to image a device or a substrate within the vacuum chamber 110.

The gas port 140 is used to introduce gases, at low pressure, into the vacuum chamber 110. For example, tungsten hexacarbonyl-W(CO)₆— may be introduced into the vacuum chamber. The FIB from the ion column 120 may be used to thermally decompose the W(CO)₆ to form a gallium/tungsten amorphous alloy. Thus W(CO)₆ may be used to deposit metal onto surfaces and to form electrical connections.

The sample manipulation stage 150 is used to move a sample relative to the FIB and/or relative to the electron beam. In this embodiment, the sample manipulation stage 150 has 5 axes of movement: 3 axes of translation (in the X, Y and Z axes) and 2 axes of rotation (for tilting a sample relative to the FIB and electron beams).

The micro-manipulator 160 comprises a sharp probe 161. In this embodiment, the micro-manipulator 160 also has 5 axes of movement: 3 axes of translation (in the X, Y and Z axes) and 2 axes of rotation (for rotating the sharp probe 161 relative to the FIB from the ion column 120). By sharp, it is meant that the dimensions of the tip of the sharp probe 161 are comparable to features of a structure being micro-machined using the FIB instrument 100.

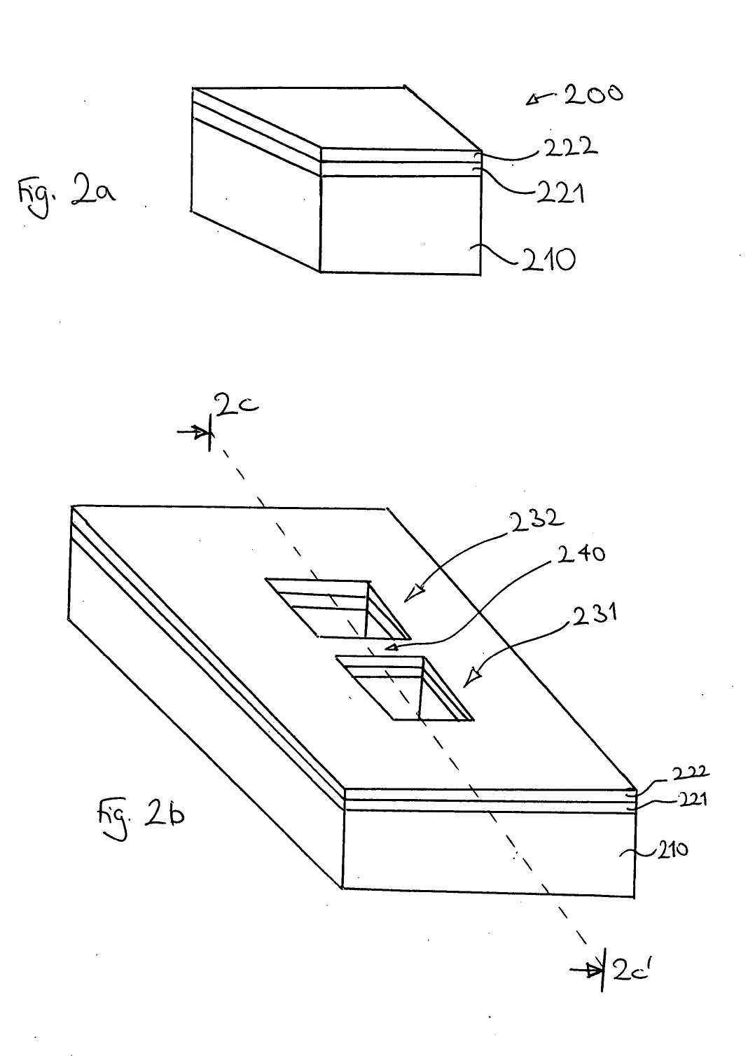

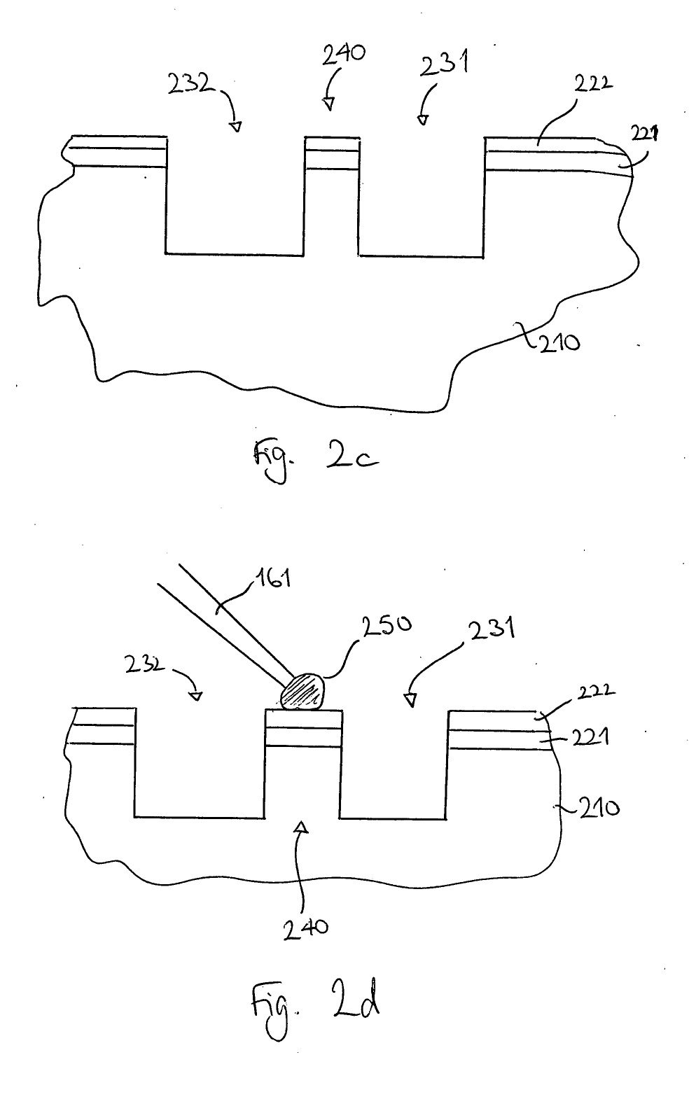

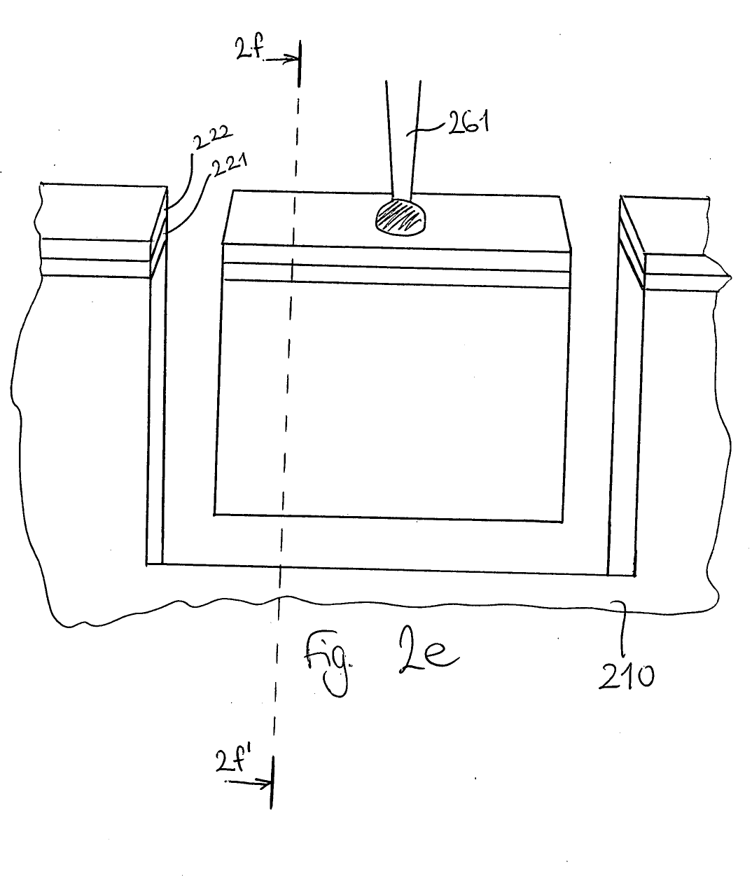

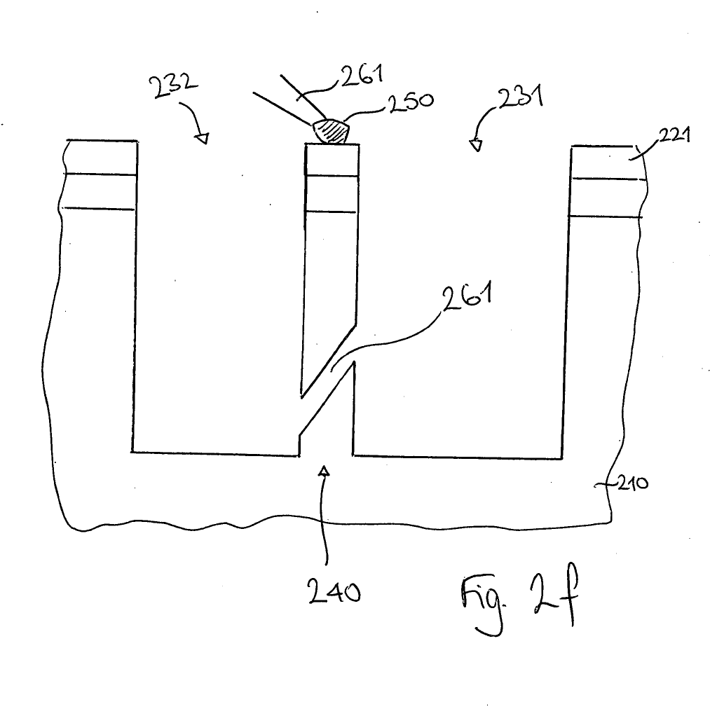

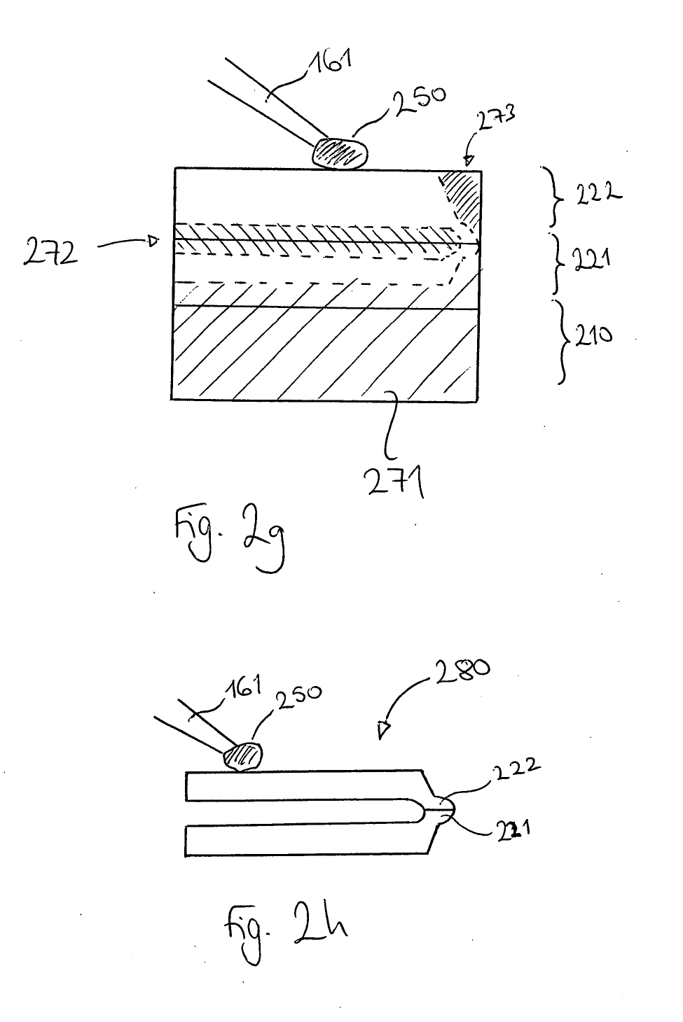

FIGS. 2a to 2h show a sequence of operations for forming a thermocouple from a material 200. The FIB instrument 100 is used to machine the material 200. A sliver 240 is formed by removing regions 231, 232 on either side of the sliver 240. Before the sliver 240 is detached from the material 200, the sharp probe 161 is “welded” to the sliver 240. FIB milling is then used to detach the sliver from the material 200. The detached sliver 240 is then further FIB milled to produce a thermocouple 280.

FIG. 2a shows the material 200 before the material 200 is machined. The material 200 comprises a substrate 210 on which is provided a first layer 221 of metal. A second layer 222 of metal overlies the first layer 221. In this embodiment, the substrate 210 is a silicon wafer (as used by the semiconductor industry), and has a thickness of 0.6 mm, the first layer 221 is copper and has a thickness of 50 nm, and the second layer 222 is iron and has a thickness of 50 nm.

FIG. 2b shows the material 200 after two regions 231, 232 have been milled into the first and second layers 221, 222 and into the substrate 210 by FIB milling. In this embodiment, the regions 231, 232 do not perforate the substrate 210 but do perforate the first and second layers 221, 222. In this embodiment, the regions 231, 232 are generally cuboid.

The sliver 240 of the material 200 remains between the two regions 231, 232. The sliver 240 comprises the substrate 210, the first layer 221 and the second layer 222. As shown, in this embodiment the sliver 240 has a length of 10 μm and a thickness of 100 nm.

FIG. 2c shows a cross-section through the plane 2c-2c′ of FIG. 2b.

FIG. 2d shows the sharp probe 161 after the sharp probe 161 has been welded to the top of the second layer 222 of the sliver 240. To weld the sharp probe 161, the micro-manipulator 160 is used to position the tip of the sharp probe 161 in contact with, or in proximity to, the second layer 222. W(CO)₆ gas is then introduced into the vacuum chamber 110 and the ion column 120 is used to irradiate the tip of the sharp probe 161 with gallium ions. The gallium ions cause the W(CO)₆ to thermally dissociate, with the result that a gallium-tungsten amorphous alloy 250 welds the tip of the sharp probe 161 to the second layer 222.

FIG. 2e shows that, in this embodiment, the ion column 120 is used to FIB mill three slots 261, 262, 263 in the sliver 240. Slot 261 is a lateral slot and is parallel to the first and second layers 221, 222. Slots 261 and 262 are vertical slots, one at each end of the lateral slot 261. The vertical slots 261 and 263 are normal to the plane of the first and second layers 221, 222. The region 231 allows the FIB to gain access to the sliver 240 without having to travel through intervening material 200.

FIG. 2f shows that the lateral slot 261 is inclined by, in this embodiment, 45° from being perpendicular to the plane of the sliver 240. The lateral slot 261 is inclined from the plane of the sliver 240 due to the fact that the FIB used for milling gains access to the sliver 240 via the region 231. The angle of inclination of the lateral slot 261 may be reduced, if required, by machining larger regions 231, 232 in the material 200 (the sample manipulation stage 150 is used to tilt the material 200 by 45° relative to the ion column 120).

FIG. 2g shows the sliver 240 after the sliver 240 has been removed from the material 200. Also shown in FIG. 2g, using phantom lines, are regions 271, 272, 273 that will be removed by FIB milling from the sliver 240 to leave a thermocouple attached to the sharp probe 161. In this embodiment, after removing the sliver 240 from the material 200, the micro-manipulator 160 is used to rotate the sliver 240 so that the plane of the sliver 240 is generally orthogonal to the ion column 120.

FIG. 2h shows the finished thermocouple 280 once the regions 271, 272, 273 have been FIB milled away. The thermocouple 280 is attached to the sharp probe 161 by the weld 250.

The thermocouple 280 is then mounted to a substrate (not shown). In this embodiment, the substrate comprises a silicon wafer having circuitry for amplifying the signal from the thermocouple 280. In this embodiment, the micro-manipulator 160 is used to position the thermocouple 280 that the thermocouple 280 is upstanding substantially perpendicular to the plane of the substrate. The ion column 120 and W(CO)₆ are then used to connect each of the electrical terminals of the thermocouple 280 to the substrate. Finally, the FIB from the ion column 120 is used to cut the gallium-tungsten amorphous alloy weld 250 so that the sharp probe 161 can be detached from the thermocouple 280.

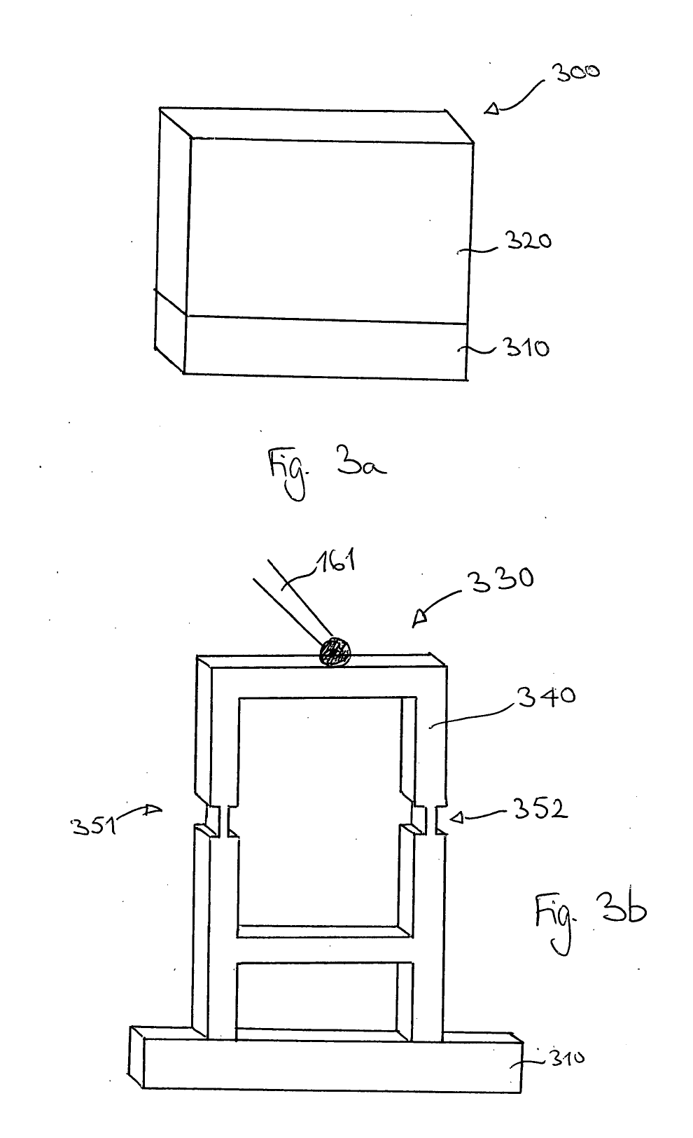

FIG. 3a shows a sliver 300 that will be sued to form a SQUID while FIG. 3b shows the finished SQUID.

FIG. 3a shows the sliver 300 before unwanted material is removed by FIB milling. In this embodiment, the sliver 300 comprises a silicon substrate 310 and a single layer 320 of niobium over the substrate; the niobium layer 320 has a thickness of 5 μm.

FIG. 3b shows the loop of the SQUID after unwanted material has been removed (the loop of the SQUID is still attached to the substrate 310). As can be seen, the SQUID 330 comprises a loop 340 of niobium with two Dayem bridge junctions 351, 352 at which the loop 340 has been narrowed to provide constrictions in the loop 340. A sharp probe 161 is welded to the loop 340.

The use of FIB milling to make the thermocouple 280 and the SQUID 330 generally leaves gallium atoms in the surfaces that have been FIB milled. The presence of the gallium atoms can be detected by their X-ray signature.

### Alternative Embodiments

Embodiments were described above in which a sharp probe 161 was attached to a sliver 240, 300 using ion-beam metal deposition. In alternative embodiments, the sharp probe 161 is attached to the sliver 240, 300 using adhesive. In yet other embodiments, a probe having a miniature fork at the tip of the probe is used (the fork is pushed onto the sliver 240, 300 and grips by friction the sliver 240, 300 between the tines of the fork). In yet further embodiments, a probe having a miniature piezoelectrically operated gripper at the tip of the probe is used to hold the sliver 240, 300.

W(CO)₆ was described above being used to form a weld between the sharp probe 161 and either the second layer 222 or the loop 340. In alternative embodiments, W(CO)₆ is not used. Instead, the sharp probe 161 is placed in contact with the second layer 222 or the loop 340 and either the ion beam or an electron beam is used to cut or melt the tip of the sharp probe 161 so that it fuses with the second layer 222 or the loop 340. In yet other embodiments, the sharp probe 161 is not melted but the material 200 (for example, the second layer 222) is melted, using an ion beam so that the sharp probe 161 becomes attached to the material 200. In yet further embodiments, an electron beam of sufficient intensity may be used to join the sharp probe 161 and the material 200.

The FIB milling was described above using gallium ions to perform the milling. In alternative embodiments, argon, for example, is used instead of gallium.

The welding was described above using gallium ions to dissociate the W(CO)₆. In alternative embodiments, the electron beam from the electron column 130 is used to dissociate the W(CO)₆ as well as for imaging.

In some embodiments, the FIB instrument is not dual beam (and thus has an ion column 120 but not an electron column 130). In such embodiments, gallium ions are also used to image the device or substrate as well as for FIB milling.

In embodiments described above, the electron column 130 was used to image a device or a substrate inside the vacuum chamber 110. In alternative embodiments, the sample manipulation stage 150 and micro-manipulator 160 are sufficiently accurate and repeatable to allow positioning of the sharp probe 161 and material 200 by dead-reckoning rather than a closed-loop process which uses visual feedback.

W(CO)₆ was described above as suitable for forming welds and for depositing tungsten. In alternative embodiments, other organometallic compounds are used.

Embodiments have been described above in which a substrate 210, 310 was used. In alternative embodiments, a substrate is not required. For example, with reference to the first and second layers 221, 222 used to form the thermocouple 280, in an alternative embodiment the first layer 221 has a thickness of the order of 0.6 mm. This thickness ensures that the first layer 221 has sufficient mechanical strength to allow the first layer 221 (and the second layer 222) to be handled. The second layer 222 has a thickness of 50 nm. To remove a sliver from the first layer 221, FIB milling is used to cut away a portion of the first layer 221. Once the sliver has been removed from the bulk material, FIB milling is performed to reduce the thickness of the first layer to 50 nm.

Embodiments described above included thermocouples and SQUIDs. Other applications include the formation of magnetic read-heads for hard disk drives. Such applications may use giant magneto-resistance (GMR) or colossal magneto-resistance (CMR). Embodiment described above included sensors. In alternative embodiments, the invention may be used to make a miniature electrical coil, for example for writing magnetic information. In some applications it may be beneficial to manufacture two devices at the same time. For example, in another embodiment, a thermocouple and a SQUID are manufactured together (using a suitable substrate). The thermocouple is used to measure the temperature of the SQUID.

An embodiment described above had a lateral slot 261 that was angled at 45°, and had regions 231, 232 that were not at the edge of the material 200. In an alternative embodiment, by locating the region 231 at an edge of the material 200, the FIB ions are directed towards the sliver 240 at an orientation that is normal to the plane of the sliver 240. In yet another embodiment, only the region 232 is used: by locating the region 232 towards an edge of the material 200, a sliver is defined between the region 232 and the edge of the material.

In embodiments described above, the sliver 240, 300 was rotated after being detached from the material 200, 300. In an alternative embodiment, rather than rotating the sliver, an FIB instrument is provided with two ion columns that are angled relative to each other. The use of such an FIB instrument allows one of the ion columns to be used to detach a sliver from the bulk material of the substrate 200, 300, and the other of the two ion columns to be used to FIB mill the sliver to the desired shape.

Those skilled in the art will appreciate that electron beam milling (using the electron column 130) may be used instead of FIB milling. They will also appreciate that gases may be introduced into the vacuum chamber 110 in order to assist with FIB or e-beam milling. Furthermore, they will also appreciate that a sacrificial protective layer (e.g. platinum) may be deposited in order to temporarily provide protection from subsequent processing steps.

In embodiments described above, electrical devices 280, 330 were produced. In alternative embodiments, non-electrical components may be produced. For example, in one embodiment, a mirror connected by a torsion spring to a post is manufactured. In this embodiment, the post is formed by lithography and then a torsion spring is attached to the post. The mirror is formed from a sliver and is then attached to the torsion spring.

In an embodiment described above, the weld 250 was re-heated in order to separate the sharp probe 161 from the sliver 240. In an alternative embodiment, for example where an adhesive is used to attach the sharp probe 161 to the sliver 240, ion beam milling may be performed so that the adhesive is removed by sputtering.

In an embodiment described above, a thermocouple 280 was attached to a semiconductor wafer having integrated signal conditioning circuitry. In alternative embodiments, a SQUID 330 may be attached to a probe assembly. The probe assembly includes electrically conductive circuit traces (i.e. “wires”) for connecting the SQUID 330 to electronic circuitry. The probe assembly also includes piezoelectric actuators for scanning the SQUID 330 so that the spatial characteristics of a magnetic field can be determined.

In embodiments described above, a thermocouple 280 and a SQUID 330 were made. In alternative embodiments, the FIB milling technique and/or the welding technique (e.g. using dissociation of tungsten hexacarbonyl) may be used to produce other structures. In one embodiment, a micro-mirror device is manufactured. In this embodiment, a cantilever is formed by cutting a sliver of a suitable material; the cantilever is then attached using the welding technique to a silicon pillar. The silicon pillar is formed as part of a silicon substrate. A mirror is then formed by cutting a sliver of a suitable material, and by welding the mirror to the non-pillar end of the cantilever. In another embodiment, the FIB milling technique is used to make diamond cantilevers for use is miniature resonator structures. Once a sliver of diamond has been formed by FIB milling, the sharp probe can be attached to the diamond either before or after the diamond sliver is FIB milled to form the required diamond cantilever from the diamond sliver. Diamond is significantly stiffer than silicon and this allows the use of higher resonance frequencies which offers improved sensitivity, for example as a mass detector. Conventional techniques are based on using lithographic techniques to make cantilevers from silicon. In yet further embodiments, single electron spin detector (for use in NMR—nuclear magnetic resonance) or accelerometers are manufactured by the methods described above. In general, an advantage of the present invention is that the present invention allows materials from a variety of processes to be combined so that the properties of the various materials can be exploited—for example, in an embodiment described above, a diamond cantilever is combined with a silicon substrate.

In an embodiment described above, two regions 231, 232 were formed that were generally parallel to each other, thus defining a sliver 240 between the two regions 231, 232. The sliver 240 was generally planar with a thickness of 100 nm. In an alternative embodiment, the regions 231, 232 are not parallel to each other but are orientated at 90° to each other, so that each region is inclined by 45° from the plane of the substrate 210. This alternative embodiment allows a sliver having a triangular cross-section to be made. Such a sliver may be used as a cantilever.

In some embodiments, a sliver is used directly (for example by attaching the sliver to a platform). In other embodiments, the sliver first requires machining (for example by ion beam machining) before the sliver can be used as a mechanical component. For example, in some embodiments a sliver is machined to form a component such as a resilient spring. In other embodiments, the sliver is machined to form an electrical device (such as the thermocouple 280 or the SQUID 330). In some embodiments, a component may have both mechanical and electrical properties. In yet further embodiments, a component or device may be optically active (e.g. lithium niobate) or may be magnetic.

Embodiments were described above in which a sharp probe 161 was used to transfer a sliver 240 from a material 200 to a platform (wherein the platform is, for example, a substrate, another probe or a probe assembly having, for example, piezoelectric actuators).

In other embodiments, the sharp probe 161 may be preformed (for example by providing the sharp probe 161 with a pair of electrical circuit traces) so that no further assembly is required once the sliver 240 has been attached to the sharp probe 161. The skilled man will, of course, appreciate that although the term “sharp probe” has been used for convenience, the actually geometry of the probe 161 will depend on the dimensions and shape of the sliver.

As those skilled in the art will appreciate, once a device (for example a thermocouple 280 or SQUID 330) has been attached to, for example, a substrate or to a probe assembly, the device together with the substrate/probe assembly may be tested and/or packaged.

1. A method of making a sliver, the method comprising the steps of:
a) ion beam milling one or more regions of a material to expose a sliver of the material;
b) attaching a probe to the sliver; and
c) ion beam milling the sliver and/or material to detach the sliver from the material.

2. A method according to claim 1, further comprising the step of:
d) ion beam milling the sliver to form a component or an electrical device.

3. A method according to claim 2, further comprising the step of:
rotating the sliver after step c) but before step d).

4. A method according to any preceding claim, wherein at least two different ion columns are used for the ion beam milling of steps a), c) or d).

5. A method according to any preceding claim, wherein the ion beam of steps a), c) or d) comprises electrons or gallium ions.

6. A method according to any preceding claim, wherein the step of attaching the probe to the sliver comprises at least one of:
using an ion beam to deposit metal to weld the probe to the sliver;
using an ion beam to weld the probe to the sliver;
using an adhesive to attach the probe to the sliver;
using a fork to attach the probe to the sliver; and
using a gripper on the probe to grip the sliver.

7. A method according to any preceding claim, further comprising the steps of:
positioning the sliver, component or electrical device in proximity to a platform; and
connecting the sliver, component or electrical device to the platform.

8. A method according to claim 7, further comprising the step of detaching the probe from the sliver, component or electrical device.

9. A method according to claim 7 or 8, wherein the step of connecting an electrical device to the platform comprises the step of electrically connecting the electrical device to one or more electrical circuit traces.

10. A method according to any one of claims 7 to 9, wherein the platform comprises a substrate, a probe or a probe assembly.

11. A method according to any one of claims 7 to 10, wherein the platform comprises circuitry for connection with the electrical device.

12. A method according to any one of claims 1 to 11, wherein the material comprises a silicon substrate, a first layer of copper, and a second layer of iron, wherein the material is machined by ion beam milling to form an electrical device, and wherein the electrical device comprises a thermocouple.

13. A method according to any one of claims 1 to 12, further comprising the step of testing and/or packaging the sliver, component or electrical device.

14. A sliver, component or electrical device made according to the method of any one of claims 1 to 13.

15. A component in combination with a platform, made according to the method of any one of claims 7 to 11.
